(19) United States
(12) Patent Application Publication
(10) Pub. No.: US 2011/0306171 A1
(43) Pub. Date: Dec. 15, 2011

(54) METHODS OF FABRICATING SEMICONDUCTOR DEVICES WITH DIFFERENTIALLY NITRIDED GATE INSULATORS

(75) Inventors: Ha-Jin Lim, Seoul (KR); Jin-Ho Do, Hwaseong-gi (KR); Weon-Hong Kim, Suwon-si (KR); Moon-Kyun Song, Anyang-si (KR); Dae-Kwon Joo, Osan-si (KR)

(73) Assignee: Samsung Electronics Co., Ltd.

(21) Appl. No.: 13/105,652

(22) Filed: May 11, 2011

(30) Foreign Application Priority Data
Jun. 10, 2010 (KR) 10-2010-0054812

(51) Int. Cl. H01L 21/8238; H01L 21/28

(52) U.S. Cl. 438/216; 438/585; 257/E21.632; 257/E21.19

(57) ABSTRACT

An insulation layer is formed on a substrate having an NMOS region and a PMOS region defined therein. A first conductive layer is formed on the insulation layer in the PMOS region, leaving a portion of the insulation layer in the NMOS region exposed. Nitriding is performed to produce a first nitrogen concentration in the insulation layer in the NMOS region and a second nitrogen concentration less than the first nitrogen concentration in the insulation layer in the PMOS region. A second conductive layer is formed on the insulation layer and the first conductive layer and the first and second conductive layers and the insulation layer are patterned to form a first gate structure and a second gate structure in the NMOS region and the PMOS region, respectively.

### CLAIM OF PRIORITY

This application claims priority under 35 USC §119 to Korean Patent Application No. 10-2010-0054812 filed on Jun. 10, 2010 in the Korean Intellectual Property Office (KIPO), the contents of which are herein incorporated by reference in their entirety.

### BACKGROUND

Example embodiments relate to methods of manufacturing semiconductor devices and, more particularly, methods of forming gate insulation layers in complementary metal oxide semiconductor (CMOS) devices.

A complementary metal oxide semiconductor (CMOS) transistor may have a gate insulation layer including a high-k dielectric material and a gate electrode including a metal.

When the gate insulation layer is formed using a high-k dielectric material, nitrogen may be implanted thereinto so that the penetrability of impurities through the gate insulation layer may be decreased and the leakage current of the gate insulation layer may be reduced. However, in order to enhance the reliability of the gate insulation layer, more effective methods of reducing the leakage current thereof are needed.

### SUMMARY

Some embodiments provide methods of fabricating a semiconductor device. An insulation layer is formed on a substrate having an NMOS region and a PMOS region defined therein. A first conductive layer is formed on the insulation layer in the PMOS region, leaving a portion of the insulation layer in the NMOS region exposed. Nitriding is performed to produce a first nitrogen concentration in the insulation layer in the NMOS region and a second nitrogen concentration less than the first nitrogen concentration in the insulation layer in the PMOS region. A second conductive layer is formed on the insulation layer and the first conductive layer and the first and second conductive layers and the insulation layer are patterned to form a first gate structure and a second gate structure in the NMOS region and the PMOS region, respectively.

In some embodiments, the first nitrogen concentration is greater than the second nitrogen concentration by about 5% to about 30%. For example, the first nitrogen concentration may be in a range from about 14% to about 30% and the second nitrogen concentration may be in a range from about 0% to about 9%.

In some embodiments, the nitridation includes implanting nitrogen using a plasma process or a thermal process. The implanting of nitrogen may use plasma nitriding using a NH₃ or N₂ plasma.

Formation of the first conductive layer may be preceded by forming an interface thin film on the substrate. Formation of the first conductive layer on the insulation layer may also be preceded by nitriding the insulation layer and annealing the insulation layer.

In some embodiments, the first and second conductive layers may include at least one of molybdenum, titanium, tantalum, hafnium, zirconium, aluminum, tungsten, tantalum silicide, tantalum aluminum, titanium silicide, titanium aluminum, molybdenum nitride, titanium nitride, tantalum nitride, hafnium nitride, zirconium nitride, aluminum nitride, tungsten nitride, tantalum silicide nitride, tantalum aluminum nitride, titanium silicide nitride and/or titanium aluminum nitride. The insulation layer may include a metal oxide including at least one of hafnium, zirconium, titanium, aluminum, lanthanum and yttrium.

In some embodiments, the first gate structure includes a first gate insulation pattern and a first gate electrode stacked on the substrate, and the second gate structure includes a second gate insulation pattern and a second gate electrode including first and second conductive patterns stacked on the substrate. Impurities may be implanted into the substrate to form source/drain regions in the substrate adjacent the first gate structure and the second gate structure.

Further embodiments provide methods in which an insulation layer is formed on a substrate having an NMOS region and a PMOS region defined therein. A mask is formed on the insulation layer in the PMOS region and a nitriding is performed to produce a first nitrogen concentration in the insulation layer in the NMOS region and a second nitrogen concentration less than the first nitrogen concentration in the insulation in the PMOS region. The mask is removed and a conductive layer is formed on the insulation layer. The conductive layer and the insulation layer are patterned to form a first gate structure in the NMOS region and a second gate structure in the PMOS region. The mask may include silicon nitride or silicon oxynitride. The conductive layer may include doped polysilicon.

Further embodiments provide a device including an NMOS transistor including a first gate structure on a substrate, the first gate structure including a first gate insulation pattern having a first nitrogen concentration and a first gate electrode on the first gate insulation pattern. The device further includes a PMOS transistor including a second gate structure on the substrate, the second gate structure including a second gate insulation pattern having a second nitrogen concentration less than the first nitrogen concentration and a second gate electrode on the second gate insulation pattern. The first nitrogen concentration may be greater than the second nitrogen concentration by about 5% to about 30%. For example, the first nitrogen concentration may be in a range from about 14% to about 30% and the second nitrogen concentration may be in a range from about 0% to about 9%.

### BRIEF DESCRIPTION OF THE DRAWINGS

Example embodiments will be more clearly understood from the following detailed description taken in conjunction with the accompanying drawings. FIGS. 1 to 8 represent non-limiting, example embodiments as described herein.

FIG. 1 is a cross-sectional view illustrating a semiconductor device in accordance with example embodiments;

FIGS. 2 to 5 are cross-sectional views illustrating operations for manufacturing the semiconductor device in FIG. 1 in accordance with example embodiments;

FIG. 6 is a cross-sectional view illustrating a semiconductor device in accordance with further example embodiments; and

FIGS. 7 to 8 are cross-sectional views illustrating operations for manufacturing the semiconductor device in FIG. 6 in accordance with example embodiments.

### DETAILED DESCRIPTION

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

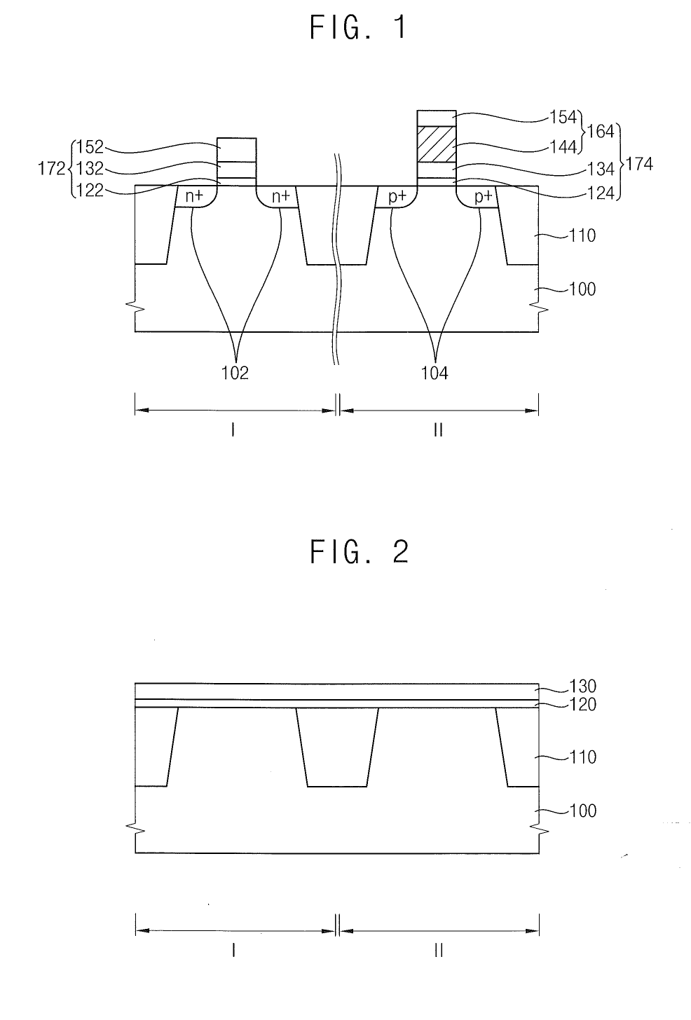

FIG. 1 is a cross-sectional view illustrating a semiconductor device in accordance with example embodiments.

Referring to FIG. 1, the semiconductor device may include a complementary metal oxide semiconductor (CMOS) transistor on a substrate 100 that may be divided into a negative channel metal oxide semiconductor (NMOS) region I and a positive channel metal oxide semiconductor (PMOS) region II. Particularly, the semiconductor device may include an NMOS transistor in the NMOS region I and a PMOS transistor in the PMOS region II.

The substrate 100 may include, for example, a silicon substrate, a silicon-germanium substrate, a silicon-on-insulator (SOI) substrate, etc. A p-type well (not shown) may be formed in the NMOS region I of the substrate 100, and an n-type well (not shown) may be formed in the PMOS region II of the substrate 100.

An isolation layer 110 may be formed on the substrate 100 to divide the substrate 100 into an active region and a field region.

The NMOS transistor may include a first gate structure 172 on the NMOS region I of the substrate 100 and first source/drain regions 102 at upper portions of the substrate 100 adjacent to the first gate structure 172.

The first gate structure 172 may include a first gate insulation layer pattern 132 and a first gate electrode 152 stacked on the substrate 100.

The first gate insulation layer pattern 132 may include a high-k dielectric material and nitrogen. For example, the high-k dielectric material may include, for example, a metal oxide containing hafnium, zirconium, titanium, aluminum, lanthanum, yttrium, etc. More particularly, the high-k dielectric material may include, for example, hafnium oxide, hafnium silicon oxide, zirconium oxide, zirconium silicon oxide, hafnium oxynitride, hafnium silicon oxynitride, zirconium oxynitride, zirconium silicon oxynitride, aluminum oxide, hafnium aluminum oxide, lanthanum oxide, hafnium lanthanum oxide, zirconium aluminum oxide, aluminum oxynitride, hafnium aluminum oxynitride, lanthanum oxynitride, hafnium lanthanum oxynitride, zirconium aluminum oxynitride, etc. These may be used alone or in combination.

The first gate insulation layer pattern 132 may include nitrogen having a first concentration. In example embodiments, the first nitrogen concentration may be about 14% to about 30%.

In example embodiments, the first gate insulation layer pattern 132 may have a thickness of about 15 Å to about 20 Å.

The first gate electrode 152 may include a metal nitride, e. g., titanium nitride. In example embodiments, the first gate electrode 152 may have a thickness equal to or less than about 300 Å.

The first source/drain regions 102 may include n-type impurities.

The PMOS transistor may include a second gate structure 174 on the PMOS region II of the substrate 100 and second source/drain regions 104 at upper portions of the substrate 100 adjacent to the second gate structure 174.

The second gate structure 174 may include a second gate insulation layer pattern 134 and a second gate electrode 164 stacked on the substrate 100.

The second gate insulation layer pattern 134 may include a high-k dielectric material and nitrogen. For example, the high-k dielectric material may include, for example, a metal oxide containing hafnium, zirconium, titanium, aluminum, lanthanum, yttrium, etc. In example embodiments, the high-k dielectric material of the second gate insulation layer pattern 134 may be substantially the same as that of the first gate insulation layer pattern 132.

The second gate insulation layer pattern 134 may include nitrogen having a second concentration, and the second nitrogen concentration may be less than the first nitrogen concentration. In example embodiments, the second nitrogen concentration may be about 0% to about 9%, which may be less than the first nitrogen concentration by about 5% to about 30%.

In example embodiments, the second gate insulation layer pattern 134 may have a thickness of about 15 Å to about 20 Å.

The second gate electrode 164 may have a first gate conductive layer pattern 144 and a second gate conductive layer pattern 154 stacked on the second gate insulation layer pattern 134. The first and second gate conductive layer patterns 144 and 154 may include a metal nitride, e. g., titanium nitride, and may be substantially the same as or different from each other. In example embodiments, the second gate conductive layer pattern 154 may have a thickness equal to or less than about 300 Å.

The second source/drain regions 104 may include p-type impurities.

First and second interface thin film patterns 122 and 124 may be further formed between the substrate 100 and the first and second gate insulation layer patterns 132 and 134, respectively. The first and second interface thin film patterns 122 and 124 may include, for example, silicon oxynitride.

The first and second gate insulation layer patterns 132 and 134 of the semiconductor device may have different nitrogen concentrations. Mobility of carriers may be greater in the second gate insulation layer patterns 134 in the PMOS region II, and a narrow width effect in the first gate insulation layer patterns 132 in the NMOS region I may be reduced or prevented so that threshold voltage and leakage current may be reduced.

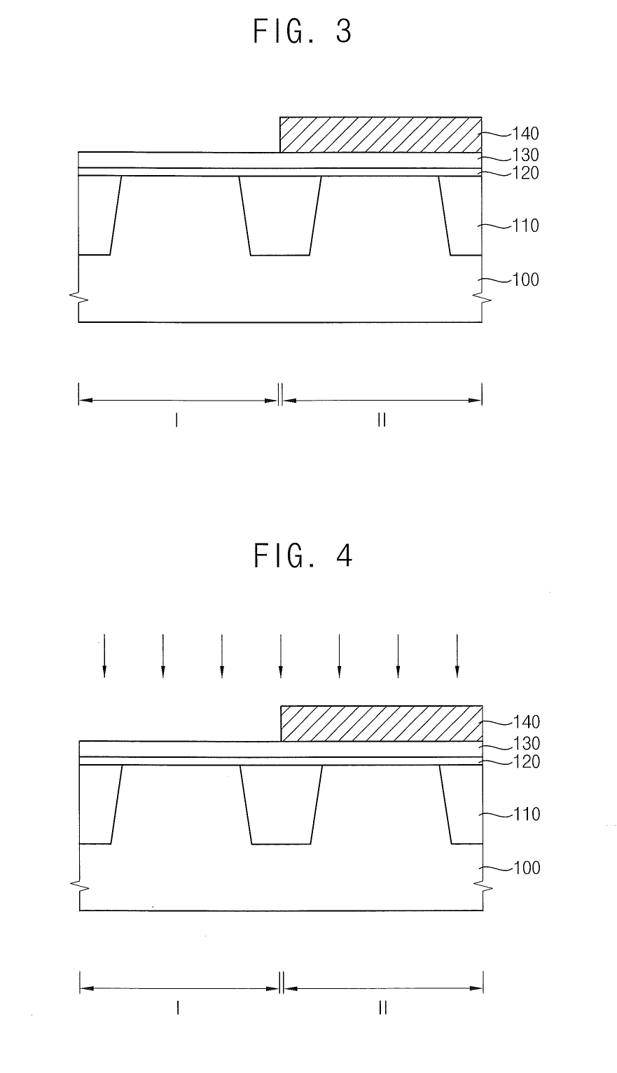

FIGS. 2 to 5 are cross-sectional views illustrating operations for manufacturing the semiconductor device in FIG. 1 in accordance with example embodiments.

Referring to FIG. 2, a substrate 100 including an NMOS region I and a PMOS region II may be provided. P-type impurities may be implanted into the NMOS region I of the substrate 100 to form a p-type well (not shown) at an upper portion of the substrate 100, and n-type impurities may be implanted into the PMOS region II of the substrate 100 to form a n-type well (not shown) at an upper portion of the substrate 100. An isolation layer 110 may be formed on the substrate 100 to define an active region and a field region in the substrate 100.

An interface thin film 120 may be formed on the substrate 100. The interface thin film 120 may be formed using silicon oxynitride. In example embodiments, the interface thin film 120 may be formed by performing a heat treatment on the substrate 100 at a high temperature under an oxygen atmosphere to grow silicon oxide, followed by plasma nitridation or thermal nitridation. In some example embodiments, the interface thin film 120 may be formed to a thickness of about 10 Å to about 15 Å.

A gate insulation layer 130 may be formed on the interface thin film 120 using a high-k dielectric material. The gate insulation layer 130 may be formed by a chemical vapor deposition (CVD) process or an atomic layer deposition (ALD) process.

The high-k dielectric material may include, for example, a metal oxide containing hafnium, zirconium, titanium, aluminum, lanthanum, yttrium, etc. More particularly, the high-k dielectric material may include, for example, hafnium oxide, hafnium silicon oxide, zirconium oxide, zirconium silicon oxide, hafnium oxynitride, hafnium silicon oxynitride, zirconium oxynitride, zirconium silicon oxynitride, aluminum oxide, hafnium aluminum oxide, lanthanum oxide, hafnium lanthanum oxide, zirconium aluminum oxide, aluminum oxynitride, hafnium aluminum oxynitride, lanthanum oxynitride, hafnium lanthanum oxynitride, zirconium aluminum oxynitride, etc. These may be used alone or in combination.

In example embodiments, the CVD process may be performed at a temperature of about 400° C. to about 500° C. under a pressure of about 1 Torr to about 5 Torr. For example, when the gate insulation layer 130 including hafnium silicon oxide is formed, HfCl₄ may serve as a hafnium source, SiH₂Cl₂ (DCS), SiH₄ or a mixture thereof may serve as a silicon source, and O₂ may serve as an oxygen source.

In example embodiments, the ALD process may be performed a temperature of about 150° C. to about 500° C. under a pressure of about 0.1 Torr to about 5 Torr. For example, in the ALD process, deposition and purging may be repeatedly performed to form the gate insulation layer 104 having a desired thickness. When the gate insulation layer 104 including hafnium silicon oxide is formed, Hf(OtBu)₄ or Hf(NEtMe)₄ may serve as a hafnium source, tetrakis dimethyl amino silicon (TDMAS) may serve as a silicon source, and O₃ or O₂ plasma may serve as an oxygen source. When the gate insulation layer 104 including hafnium aluminum oxide is formed, trimethyl aluminum (TMA), AlCl₃, AlH₃N(CH₃)₃ may serve as an aluminum source.

In example embodiments, the gate insulation layer 130 may be formed to a thickness of about 15 Å to about 20 Å.

A preliminary nitridation treatment may be further performed on a top surface of the gate insulation layer 130 including a metal oxide so that the gate insulation layer 130 may be more densified. In an example embodiment, the preliminary nitridation treatment may be performed by implanting a gas having nitrogen into the gate insulation layer 130 in a plasma atmosphere.

For example, the gas having nitrogen may include N₂, NO, N₂O, O₂, NH₃, etc. These may be used alone or in combination. By the preliminary nitridation treatment, impurities generated in subsequent processes may not penetrate the gate insulation layer 130.

An annealing process may be further performed on the gate insulation layer 130 at a high temperature of about 750 to about 1,050° C. under an inactive gas atmosphere, so that the gate insulation layer 130 may be densified and the dry etching rate thereof in a subsequent patterning process may be controlled.

If the temperature of the annealing process is less than about 750° C., the etching rate of the gate insulation layer 130 in the pattern process may be undesirably increased, and if the temperature of the annealing process is above about 1,050° C., the gate insulation layer 130 may be undesirably easily crystallized.

Referring to FIG. 3, a gate conductive layer 140 may be formed on the gate insulation layer 130 in the PMOS region II.

Particularly, a first gate conductive layer 140 may be formed on the gate insulation layer 130 using a metal, a metal silicide and/or a metal nitride thereof. For example, the first gate conductive layer 140 may include molybdenum, titanium, tantalum, hafnium, zirconium, aluminum, tungsten, tantalum silicide, tantalum aluminum, titanium silicide, titanium aluminum, molybdenum nitride, titanium nitride, tantalum nitride, hafnium nitride, zirconium nitride, aluminum nitride, tungsten nitride, tantalum silicide nitride, tantalum aluminum nitride, titanium silicide nitride, titanium aluminum nitride, etc. In an example embodiment, the first gate conductive layer 140 may be formed using titanium nitride.

The first gate conductive layer 140 may be formed by a CVD process or a sputtering process.

The CVD process may be performed using a source gas including TiCl₄ and a reaction gas including NH₃. In example embodiments, the source gas and the reaction gas may have flow rates of about 10 sccm and 1,000 sccm, respectively, and the CVD process may be performed at a temperature of about 300° C. to about 500° C. under a pressure of about 0.1 Torr to about 2 Torr. In an example embodiment, the first gate conductive layer 140 may be formed to a thickness of about 30 Å to about 80 Å.

The first gate conductive layer 140 may be partially removed.

Particularly, a photoresist layer (not shown) may be formed on the first gate conductive layer 140 and patterned to form a photoresist pattern (not shown) covering a portion of the first conductive layer 140 in the PMOS region II. The first gate conductive layer 140 may be etched using the photoresist pattern as an etching mask, so that the first gate conductive layer 140 may remain on the gate insulation layer 130 in the PMOS region II.

Referring to FIG. 4, a nitridation process may be performed on the substrate 100 having the first gate conductive layer 140 and the gate insulation layer 130 thereon.

The nitridation process may include, for example, a plasma nitridation process or a thermal nitridation process. The plasma nitridation process may be performed using NH₃ or N₂ in a plasma state at a room temperature or a temperature equal to or less than about 600° C. The thermal nitridation process may be performed using NH₃ at a temperature of about 500° C. to about 1,000° C.

In example embodiments, the nitridation process may be performed for about 40 seconds to about 60 seconds, and the duration time may be controlled according to the thickness of the gate insulation layer 130.

By the nitridation process, nitrogen may be implanted directly into the gate insulation layer 130 in the NMOS region I, however, through the first gate conductive layer 140 into the gate insulation layer 130 in the PMOS region II. Thus, a portion of the gate insulation layer 130 in the PMOS region II may have a nitrogen concentration less than that of a portion of the gate insulation layer 130 in the NMOS region I. That is, the portion of the gate insulation layer 130 in the NMOS region I may have a first nitrogen concentration, and the portion of the gate insulation layer 130 in the PMOS region II may have a second nitrogen concentration less than the first nitrogen concentration.

In example embodiments, the first nitrogen concentration may be about 14% to about 30%, and the second nitrogen concentration may be about 0% to about 9%. Thus, the first nitrogen concentration may be greater than the second nitrogen concentration by about 5% to about 30%. If the first nitrogen concentration is less than about 14%, the portion of the gate insulation layer 130 in the NMOS region I may have poor insulative characteristics and may react with oxygen to increase the threshold voltage of an NMOS transistor subsequently formed. If the first nitrogen concentration is above about 30%, the mobility of electrons may be decreased. If the second nitrogen concentration is out of the above range, the portion of the gate insulation layer 130 in the PMOS region II may have poor reliability and hot carrier injection (HCI) may occur therein.

By the above nitridation process, a first gate insulation layer pattern 132 (see FIG. 5) of the NMOS transistor may have a high nitrogen concentration, and thus the decrease of the electron mobility or the increase of the threshold voltage in a channel may be reduced or prevented and the leakage current may be reduced even when the first gate insulation layer pattern 132 has a thin thickness. Additionally, a second gate insulation layer pattern 134 (see FIG. 5) of a PMOS transistor subsequently formed may have a lower nitrogen concentration than the first gate insulation layer pattern 132, and thus negative bias temperature instability current stress and HCI may be reduced or prevented and the PMOS transistor may have good operation characteristics.

In an example embodiment, the nitridation process may be performed independently from the subsequent formation of a second gate conductive layer 150. Alternatively, the nitridation process and the formation of a second gate conductive layer 150 may be performed in-situ in the same chamber. In this case, the two processes may be performed without breaking vacuum, and thus the out-diffusion of nitrogen may be reduced or prevented.

Referring to FIG. 5, the second gate conductive layer 150 may be formed on the first gate conductive layer 140 and the first gate insulation layer 130.

The second gate conductive layer 150 may be formed using, for example, a metal nitride. The second gate conductive layer 150 may be formed using a material substantially the same as or different from that of the first gate conductive layer 140. The second gate conductive layer 150 may be formed by a CVD process or a sputtering process.

The CVD process may be performed using, for example, a source gas including TiCl₄ and a reaction gas including NH₃. In example embodiments, the source gas and the reaction gas may have flow rates of about 10 sccm and 1,000 sccm, respectively, and the CVD process may be performed at a temperature of about 300° C. to about 500° C. under a pressure of about 0.1 Torr to about 2 Torr. In an example embodiment, the first gate conductive layer 140 may be formed to a thickness of about 30 Å to about 70 Å.

The second gate conductive layer 150, the first gate conductive layer 140, the gate insulation layer 130 and the interface thin film 120 may be patterned to form a first gate structure 172 and a second gate structure 174 on the substrate 100 in the NMOS region I and in the PMOS region II, respectively.

Referring again to FIG. 1, the first gate structure 172 may have a first interface thin film pattern 122, the first gate insulation layer pattern 132 and a first gate electrode 152 stacked on the substrate 100. The second gate structure 174 may have a second interface thin film pattern 124, the second gate insulation layer pattern 134 and a second gate electrode 164 stacked on the substrate 100. The second gate electrode 164 may have a first gate conductive layer pattern 144 and a second gate conductive layer pattern 154 stacked on the second gate insulation layer pattern 134.

The first gate electrode 152 may have a work function proper for the NMOS transistor. The first gate conductive layer pattern 144 may have a relatively high nitrogen concentration, and thus the second gate electrode 164 including the first gate conductive layer pattern 144 may have a work function relatively high and proper for the PMOS transistor.

Impurities may be implanted into the substrate 100 using the first and second gate structures 172 and 174 as an ion implantation mask.

Particularly, first impurities may be implanted into the NMOS region I of the substrate 100 to form first source/drain regions 102, and second impurities may be implanted into the PMOS region II of the substrate 100 to form second source/drain regions 104. The first impurities may include n-type impurities, e. g., phosphorous, and the second impurities may include p-type impurities, e. g., boron.

Thus, the CMOS transistor structure may be manufactured.

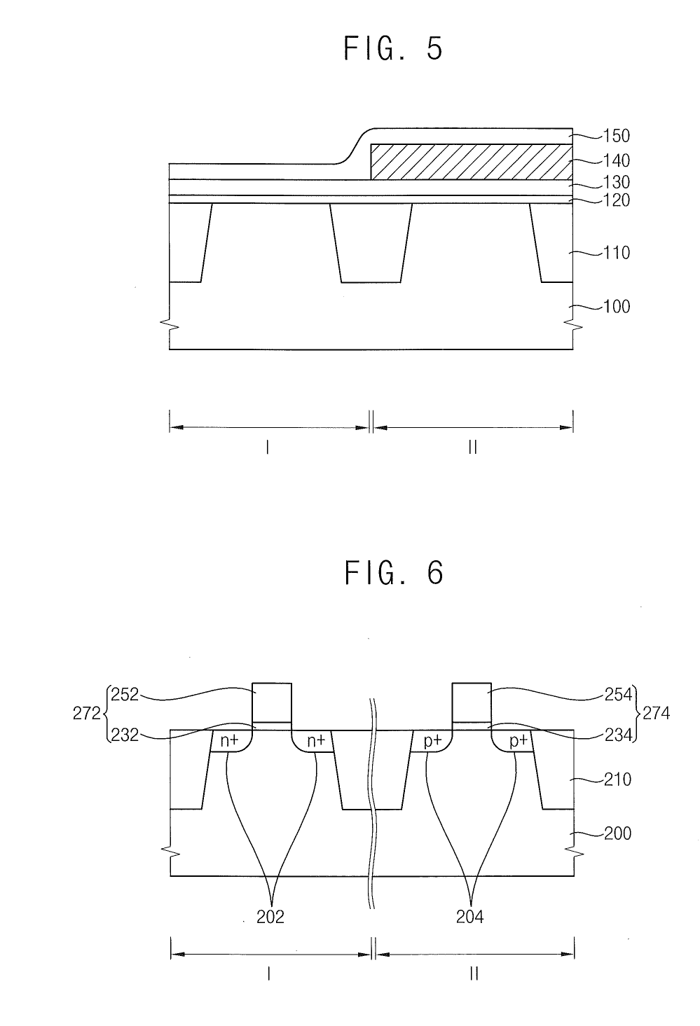

FIG. 6 is a cross-sectional view illustrating a semiconductor device in accordance with other example embodiments.

Referring to FIG. 6, the semiconductor device may include a CMOS transistor structure on a substrate 200 that may be divided into an NMOS region I and a PMOS region II. Particularly, the semiconductor device may include an NMOS transistor in the NMOS region I and a PMOS transistor in the PMOS region II.

An isolation layer 210 may be formed on the substrate 200 to divide the substrate 200 into an active region and a field region.

The NMOS transistor may include a first gate structure 272 on the NMOS region I of the substrate 200 and first source/drain regions 202 at upper portions of the substrate 200 adjacent to the first gate structure 272.

The first gate structure 272 may include a first gate insulation layer pattern 232 and a first gate electrode 252 stacked on the substrate 200.

The first gate insulation layer pattern 232 may include, for example, nitrogen and silicon oxide or silicon oxynitride. The first gate insulation layer pattern 232 may include nitrogen having a first concentration. In example embodiments, the first gate insulation layer pattern 232 may have a thickness of about 10 to about 50 Å.

The first gate electrode 252 may include doped polysilicon. In example embodiments, the first gate electrode 252 may have a thickness equal to or less than about 1,000 Å.

The first source/drain regions 202 may include n-type impurities.

The PMOS transistor may include a second gate structure 274 on the PMOS region II of the substrate 200 and second source/drain regions 204 at upper portions of the substrate 200 adjacent to the second gate structure 274.

The second gate structure 274 may include a second gate insulation layer pattern 234 and a second gate electrode 264 stacked on the substrate 200.

The second gate insulation layer pattern 234 may include, for example, nitrogen and silicon oxide or silicon oxynitride. The second gate insulation layer pattern 234 may include nitrogen having a second concentration, and the second nitrogen concentration may be less than the first nitrogen concentration. In example embodiments, the second gate insulation layer pattern 234 may have a thickness of about 10 Å to about 50 Å.

The second gate electrode 264 may include, for example, doped polysilicon. In example embodiments, the second gate conductive layer pattern 254 may have a thickness equal to or less than about 1,000 Å.

The second source/drain regions 204 may include p-type impurities.

The first and second gate insulation layer patterns 232 and 234 of the semiconductor device, which has the gate electrodes 252 and 254 including doped polysilicon, may have different nitrogen concentrations, and thus the mobility of carriers may not be decreased in the second gate insulation layer patterns 234 in the PMOS region II, and a narrow width effect in the first gate insulation layer patterns 232 in the NMOS region I may be reduced or prevented so that an increase of threshold voltage and leakage current may be reduced.

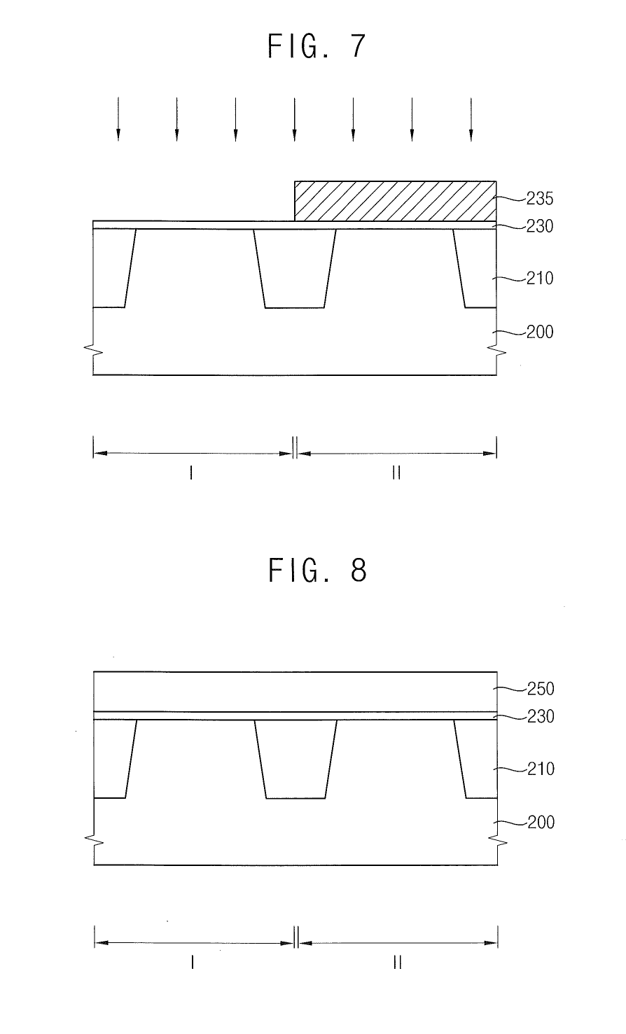

FIGS. 7 to 8 are cross-sectional views illustrating operations for manufacturing the semiconductor device in FIG. 6 in accordance with example embodiments.

Referring to FIG. 7, a substrate 200 including an NMOS region I and a PMOS region II may be provided. An isolation layer 210 may be formed on the substrate 200 to define an active region and a field region in the substrate 200.

A gate insulation layer 230 may be formed on the substrate 200 using silicon oxide or silicon oxynitride. In an example embodiment, the gate insulation layer 230 may be formed by thermally oxidizing a top surface of the substrate 200. In another example embodiment, the gate insulation layer 230 may be formed by depositing silicon oxide through a CVD process and by performing a plasma nitridation treatment or a heat nitridation treatment thereon. The gate insulation layer 230 may be formed to a thickness of about 10 Å to about 50 Å.

A second gate insulation layer (not shown) may be further formed on the gate insulation layer using a high-k dielectric material.

A mask layer may be formed on the gate insulation layer 230, and the mask layer may be partially removed.

Particularly, a photoresist layer (not shown) may be formed on the mask layer and patterned to form a photoresist pattern covering a portion of the mask layer in the PMOS region II. The mask layer may be etched using the photoresist pattern as an etching mask to form a mask 235 on the gate insulation layer 230 in the PMOS region II.

A nitridation process may be performed on the substrate 200 having the mask 235 and the gate insulation layer 230 thereon. The nitridation process may include, for example, a plasma nitridation process or a thermal nitridation process. The plasma nitridation process may be performed using NH₃ or N₂ in a plasma state at a room temperature or a temperature equal to or less than about 600° C. The thermal nitridation process may be performed using NH₃ at a temperature of about 500° C. to about 1,000° C. In example embodiments, the nitridation process may be performed for about 40 seconds to about 60 seconds, and the duration time may be controlled according to the thickness of the gate insulation layer 230.

By the nitridation process, nitrogen may be implanted directly into the gate insulation layer 230 in the NMOS region I and through the mask 235 into the gate insulation layer 230 in the PMOS region II. Thus, a portion of the gate insulation layer 230 in the PMOS region II may have a nitrogen concentration less than that of a portion of the gate insulation layer 230 in the NMOS region I. The portion of the gate insulation layer 230 in the NMOS region I may have a first nitrogen concentration, and the portion of the gate insulation layer 230 in the PMOS region II may have a second nitrogen concentration less than the first nitrogen concentration. In example embodiments, the first nitrogen concentration may be about 14% to about 30%, and the second nitrogen concentration may be about 0% to about 9%. Thus, the first nitrogen concentration may be greater than the second nitrogen concentration by about 5% to about 30%.

Referring to FIG. 8, a gate conductive layer 250 may be formed on the gate insulation layer 230.

In example embodiments, the gate conductive layer 250 may be formed using doped polysilicon. The gate conductive layer 250 may be formed by a CVD process. The CVD process may be performed using a silicon source gas including SiH₄ at a temperature of about 600° C. to about 650° C. under a pressure of about 25 Pa to about 150 Pa. In an example embodiment, the gate conductive layer 240 may be formed to a thickness equal to or less than about 1,000 Å.

N-type impurities and p-type impurities may be implanted into the gate conductive layer 250 in the NMOS region I and the PMOS region II, respectively, so that the gate conductive layer 250 may have a work function proper for an NMOS transistor and a PMOS transistor formed in the NMOS region I and a PMOS region II, respectively.

Referring again to FIG. 6, the gate conductive layer 250 and the gate insulation layer 230 may be patterned by a photolithography process to form a first gate structure 272 and a second gate structure 274 on the substrate 200 in the NMOS region I and the PMOS region II, respectively.

Impurities may be implanted into the substrate 200 using the first and second gate structures 272 and 274 as an ion implantation mask. Particularly, first impurities may be implanted into the NMOS region I of the substrate 200 to form first source/drain regions 202, and second impurities may be implanted into the PMOS region II of the substrate 200 to form second source/drain regions 204. The first impurities may include n-type impurities, e. g., phosphorous, and the second impurities may include p-type impurities, e. g., boron.

Thus, the CMOS transistor structure may be manufactured.

In example embodiments, the substrate 200 may further include a core region and an in/out line region in which the gate insulation layer 230 may have a different thickness. Particularly, a gate structure including a gate insulation layer pattern having a relatively thin thickness may be formed in the core region, and a gate structure including a gate insulation layer pattern having a relatively thick thickness may be formed in the in/out line region. Even in the core region and the in/our line region, a mask may be formed on a gate insulation layer, and a nitridation process may be performed on the gate insulation layer. Thus, the gate insulation layer having different thicknesses in different regions may have different nitrogen concentrations.

In the above-described operations for manufacturing the semiconductor device, a nitridation process may be performed using the mask 235, so that the gate insulation layer 230 may have different nitrogen concentrations in the NMOS region I and the PMOS region II. Additionally, the gate conductive layer 250 may be formed on the gate insulation layer 230 using doped polysilicon. Accordingly, a CMOS transistor structure having gate electrodes including doped polysilicon may have good electrical characteristics and good reliability.

According to example embodiments, a gate insulation layer may be formed on a substrate having an NMOS region and a PMOS region, a conductive layer may be formed on the gate insulation layer in the PMOS region, and a nitridation process may be performed on the substrate. Thus, nitrogen introduced into the gate insulation layer may be blocked by the conductive layer in the PMOS region, so that the gate insulation layer may have a relatively high nitrogen concentration in the NMOS region. Accordingly, the mobility of carriers may not be decreased in the PMOS region, and the increase of threshold voltage and leakage current may be reduced in the NMOS region.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A method of fabricating a semiconductor device, the method comprising: forming an insulation layer on a substrate having an NMOS region and a PMOS region defined therein;
forming a first conductive layer on the insulation layer in the PMOS region, leaving a portion of the insulation layer in the NMOS region exposed;
nitriding to produce a first nitrogen concentration in the insulation layer in the NMOS region and a second nitrogen concentration less than the first nitrogen concentration in the insulation layer in the PMOS region;
forming a second conductive layer on the insulation layer and the first conductive layer; and
patterning the first and second conductive layers and the insulation layer to form a first gate structure and a second gate structure in the NMOS region and the PMOS region, respectively.

2. The method of claim 1, wherein the first nitrogen concentration is greater than the second nitrogen concentration by about 5% to about 30%.

3. The method of claim 1, wherein the first nitrogen concentration is in a range from about 14% to about 30% and wherein the second nitrogen concentration is in a range from about 0% to about 9%.

4. The method of claim 1, wherein nitriding to produce a first nitrogen concentration in the insulation layer in the NMOS region and a second nitrogen concentration less than the first nitrogen concentration in the insulation layer in the PMOS region comprises implanting nitrogen using a plasma process or a thermal process.

5. The method of claim 4, wherein implanting nitrogen using a plasma process or a thermal process comprises plasma nitriding using a NH₃ or N₂ plasma.

6. The method of claim 1, wherein forming a first conductive layer on the insulation layer in the PMOS region is preceded by forming an interface thin film on the substrate.

7. The method of claim 1, wherein forming a first conductive layer on the insulation layer in the PMOS region is preceded by:
nitriding the insulation layer; and
annealing the insulation layer.

8. The method of claim 1, wherein the first and second conductive layers comprise at least one of molybdenum, titanium, tantalum, hafnium, zirconium, aluminum, tungsten, tantalum silicide, tantalum aluminum, titanium silicide, titanium aluminum, molybdenum nitride, titanium nitride, tantalum nitride, hafnium nitride, zirconium nitride, aluminum nitride, tungsten nitride, tantalum silicide nitride, tantalum aluminum nitride, titanium silicide nitride and/or titanium aluminum nitride.

9. The method of claim 1, wherein the first gate structure comprises a first gate insulation pattern and a first gate electrode stacked on the substrate, and wherein the second gate structure comprises a second gate insulation pattern and a second gate electrode comprising first and second conductive patterns stacked on the substrate.

10. The method of claim 1, further comprising implanting impurities into the substrate to form source/drain regions in the substrate adjacent the first gate structure and the second gate structure.

11. The method of claim 1, wherein the insulation layer comprises a metal oxide comprising at least one of hafnium, zirconium, titanium, aluminum, lanthanum and yttrium.

12. A method of fabricating a semiconductor device, the method comprising:
forming an insulation layer on a substrate having an NMOS region and a PMOS region defined therein;
forming a mask on the insulation layer in the PMOS region;
nitriding to produce a first nitrogen concentration in the insulation layer in the NMOS region and a second nitrogen concentration less than the first nitrogen concentration in the insulation in the PMOS region;
removing the mask;
forming a conductive layer on the insulation layer; and
patterning the conductive layer and the insulation layer to form a first gate structure in the NMOS region and a second gate structure in the PMOS region.

13. The method of claim 12, wherein the mask comprises silicon nitride or silicon oxynitride.

14. The method of claim 12, wherein the conductive layer comprises doped polysilicon.

15.-20. (canceled)
